(19) United States
(12) Patent Application Publication
(10) Pub. No.: US 2009/0145656 A1
(43) Pub. Date: Jun. 11, 2009

(54) Electrical device

(75) Inventor: Beat Tschudin, Reinach (CH)

Correspondence Address: BACON & THOMAS, PLLC, 625 SLATERS LANE, FOURTH FLOOR, ALEXANDRIA, VA, 22314-1176, US

(73) Assignee: Endress + Hauser Flowtec AG, Reinach (CH)

(21) Appl. No.: 12/314,034

(22) Filed: Dec. 3, 2008

Related U.S. Application Data
(60) Provisional application No. 60/996,747, filed on Dec. 4, 2007.

(30) Foreign Application Priority Data
Dec. 4, 2007 (DE) DE102007058608.8

(51) Int. Cl. H01L 23/28

(52) U.S. Cl. 174/521

(57) ABSTRACT

A device embodied as a measuring- and/or switching-device of industrial measurements and automation technology and/or an electronic, device, has at least one housing with at least one chamber, especially a chamber accommodating electrical, electronic and/or electromechanical components and/or assemblies of the device, especially a chamber which is sealed pressure-tightly and/or explosion-resistantly. A space of such chamber surrounding the components and/or assemblies is at least partially, especially completely and/or in an ignition protection type “Ex-m” guaranteeing manner, filled with embedding compound. Additionally incorporated in the embedding compound are hollow bodies, especially essentially spherically shaped, hollow bodies and/or hollow bodies filled with gas, especially hollow bodies e.g. in the form of microballoons.

This application is a Nonprovisional Application which claims the benefit of U.S. Provisional Application Ser. No. 60/996,747, which was filed on Dec. 4, 2007.

### TECHNICAL FIELD

The invention relates to a device, especially a device embodied as a measuring- and/or switching-device of industrial measurements- and automation-technology, and/or an electronic device, having at least one housing. The housing has at least one chamber accommodating components and/or assemblies of the device. A space of such chamber surrounding the components and/or assemblies is filled with embedding compound.

### BACKGROUND DISCUSSION

In industrial process-measurements technology, especially also in connection with the automation of chemical or value-adding processes and/or automated control of industrial plants, process-near, electrical measuring- and/or switching-devices, so called field devices, such as e.g. Coriolis mass-flow measuring devices, density-measuring devices, magneto-inductive flow measuring devices, vortex flow measuring devices, ultrasonic flow measuring devices, thermal mass-flow measuring devices, pressure measuring devices, fill level measuring devices, temperature measuring devices, pH-value measuring devices etc., are applied, and serve for producing measured values representing, analogly or digitally, process variables, as well as producing measured-value signals lastly carrying such process variables. The process variables to be registered can include, depending on application, for example, a mass flow, a density, a viscosity, a fill- or limit-level, a pressure or a temperature, or the like, of a liquid, powdered, vaporous or gaseous medium conveyed or held in a suitable container, such as e.g. a pipeline or a tank.

For registering the respective process variables, field devices of the aforementioned kind include, in each case, a suitable physical-to-electrical or chemical-to-electrical, measuring transducer. This is, most often, set in a wall of the container containing the medium or in the course of a line conveying the medium, for example, a pipeline, and serves for producing at least one electrical measurement signal appropriately corresponding with the process variable to be registered. For processing the measurement signal, the measuring transducer is further connected with an operating- and evaluating-circuit provided in a field device electronics of the field device, internal to the measuring device and serving for further processing or evaluation of the at least one measurement signal as well as also for generating corresponding measured value signals. Further examples of such measuring devices known, per se, to those skilled in the art, especially also details concerning their application and their operation, are described sufficiently and in detail in, among others, the following documents: WO-A 03/048874, WO-A 02/45045, WO-A 02/103327, WO-A 02/086426, WO-A 01/02816, WO-A 00/48157, WO-A 00/36 379, WO-A 00/14 485, WO-A 95/16 897, WO-A 88/02 853, WO-A 88/02 476, U.S. Pat. No. 7,134,348, U.S. Pat. No. 7,133,727, U.S. Pat. No. 7,075,313, U.S. Pat. No. 7,073,396, U.S. Pat. No. 7,032,045, U.S. Pat. No. 6,854,055, U.S. Pat. No. 6,799,476, U.S. Pat. No. 6,776,053, U.S. Pat. No. 6,769,301, U.S. Pat. No. 6,662,120, U.S. Pat. No. 6,640,308, U.S. Pat. No. 6,577,989, U.S. Pat. No. 6,574,515, U.S. Pat. No. 6,556,447, U.S. Pat. No. 6,539,819, U.S. Pat. No. 6,535,161, U.S. Pat. No. 6,512,358, U.S. Pat. No. 6,487,507, U.S. Pat. No. 6,480,131, U.S. Pat. No. 6,476,522, U.S. Pat. No. 6,397,683, U.S. Pat. No. 6,366,436, U.S. Pat. No. 6,352,000, U.S. Pat. No. 6,311,136, U.S. Pat. No. 6,285,094, U.S. Pat. No. 6,269,701, U.S. Pat. No. 6,236,322, U.S. Pat. No. 6,140,940, U.S. Pat. No. 6,051,783, U.S. Pat. No. 6,014,100, U.S. Pat. No. 6,006,609, U.S. Pat. No. 5,959,372, U.S. Pat. No. 5,796,011, U.S. Pat. No. 5,742,225, U.S. Pat. No. 5,742,225, U.S. Pat. No. 5,706,007, U.S. Pat. No. 5,687,100, U.S. Pat. No. 5,672,975, U.S. Pat. No. 5,604,685, U.S. Pat. No. 5,535,243, U.S. Pat. No. 5,469,748, U.S. Pat. No. 5,416,723, U.S. Pat. No. 5,363,341, U.S. Pat. No. 5,359,881, U.S. Pat. No. 5,231,884, U.S. Pat. No. 5,207,101, U.S. Pat. No. 5,131,279, U.S. Pat. No. 5,068,592, U.S. Pat. No. 5,065,152, U.S. Pat. No. 5,052,230, U.S. Pat. No. 4,926,340, U.S. Pat. No. 4,850,213, U.S. Pat. No. 4,768,384, U.S. Pat. No. 4,716,770, U.S. Pat. No. 4,656,353, U.S. Pat. No. 4,617,607, U.S. Pat. No. 4,594,584, U.S. Pat. No. 4,574,328, U.S. Pat. No. 4,524,610, U.S. Pat. No. 4,468,971, U.S. Pat. No. 4,317,116, U.S. Pat. No. 4,308,754, U.S. Pat. No. 3,878,725, U.S. Pat. No. 2007/0217091, U.S. Pat. No. 2006/0179956, US-A 2006/0161359, US-A 2006/0120054, US-A 2006/0112774, US-A 2006/0096390, US-A 2005/0139015, US-A 2004/0117675, EP-A 1 669 726, EP-A 1 158 289, EP-A 1 147 463, EP-A 1 058 093, EP-A 984 248, EP-A 591 926, EP-A 525 920, DE-A 102005 032 808, DE 100 41 166, DE-A 44 12 388, DE-A 39 34 007 or DE-A 37 11 754

In the case of a large number of field devices of the kind being discussed here, the measuring transducer is additionally so driven by a driver signal generated, at least at times during operation, by the operating- and evaluating-circuit for producing the measurement signal, that the measuring transducer acts, in a manner suited for the measuring, at least mediately, or, however, also via a probe directly contacting the medium, directly, on the medium, in order to bring about, there, reactions appropriately corresponding with the measured variable to be registered. The driver signal can, in such case, be appropriately controlled, for example, as regards an electrical current level, a voltage level and/or a frequency. Nameable as examples for such active measuring transducers, thus measuring transducers appropriately converting an electrical driver signal in the medium, are, especially, flow measuring transducers serving for the measurement of media flowing at least at times, and having e.g. at least one coil driven by the driver signal and producing a magnetic field, or having at least one ultrasonic transmitter driven by the driver signal, or, however also, fill level- and/or limit level-transducers, such as e.g. those having a freely radiating microwave antenna, a Goubau-line, or a vibrating, immersible body serving for the measurement and/or monitoring of fill levels in a container.

Devices of the kind being discussed here have, additionally, at least one housing containing at least one chamber, usually a chamber sealed pressure-tightly and/or explosion-resistantly, for accommodating electrical, electronic and/or electromechanical components and/or assemblies of the device. Thus, field devices of the described kind include, most often, a comparatively robust, especially impact-, pressure-, and/or weather-resistant, electronics-housing, for accommodating the field device electronics. This can, as proposed e.g. in U.S. Pat. No. 6,397,683 or WO-A 00/36379, be remotely arranged from the field device and connected therewith only via a flexible line; it can, however, also, as disclosed e.g. in EP-A 903 651 or EP-A 1 008 836, be directly arranged on the measuring transducer or on a housing separately housing the measuring transducer. On occasion, the electronics-housing can, such as, for example, disclosed in EP-A 984 248, U.S. Pat. No. 4,594,584, U.S. Pat. No. 4,716,770 or U.S. Pat. No. 6,352,000, also serve for accommodating some mechanical components of the measuring transducer, such as e.g. membrane-, rod-, shell- or tubular, deformation- or vibration-bodies themselves deforming in the face of mechanical action during operation; compare, in this connection, also the initially mentioned U.S. Pat. No. 6,352,000 or U.S. Pat. No. 6,051,783.

In the case of field devices, the pertinent field device electronics is usually electrically connected via appropriate electrical lines to a superordinated electronic data processing system, most often spatially remotely arranged from the particular device and, most often, also spatially distributed, to which the measured values produced by the particular field device are forwarded, near in time, by means of measured-value signals appropriately carrying the measured values. Electrical devices of the described kind are additionally usually connected with one another and/or with suitable electronic process-controls by means of a data transmission network provided within the superordinated data processing system. The process controls can include, for example, on-site installed, programmable logic controllers or process-control computers installed in a remote control room, where the measured values produced by means of the measuring device, digitized in suitable manner and appropriately coded, are forwarded. By means of such process-control computers, the transmitted, measured values can be further processed and, as appropriate, measurement results visualized e.g. on monitors and/or converted into control signals for other field devices constructed as actuators, such as e.g. magnetically operated valves, electric motors, etc. Since modern measuring arrangements can, most often, also be directly monitored, and, if conditions require, controlled and/or configured, from such control computers, operating data intended for the measuring device are likewise dispatched in corresponding manner via aforementioned data transmission networks, which are, most often, hybrid, as regards transmission physics and/or transmission logic. Accordingly, the data processing system serves usually also for conditioning, for example suitably digitizing and, as conditions require, converting into a corresponding telegram, and/or on-site evaluating the measured values signal delivered by the measuring device, appropriately according to the requirements of downstream data transmission networks. For this, such data processing systems include, electrically coupled with the respective connecting lines, evaluating circuits, which pre- and/or further-process, as well as, in case required, suitably convert, measured values received by the respective measuring- and/or switch-device. Serving for data transmission in such industrial data processing systems are, at least sectionally, especially serial, fieldbusses, such as e.g. FOUNDATION FIELDBUS, RACKBUS-RS 485, PROFIBUS, etc., or for example, also networks on the basis of the ETHERNET-standard, as well as the corresponding, most often, intermodally standardized, transmission-protocols.

Besides the evaluating circuits required for the processing and converting of the measured values delivered by the, in each case, connected field device, such superordinated data processing systems have, most often, for supplying the connected measuring- and/or switching-devices with electrical energy, also electrical supply circuits, which provide a supply voltage, on occasion fed directly by the connected fieldbus, for the pertinent field device electronics and drive electrical currents flowing through the electrical lines connected thereto, as well as through the respective field device electronics. A supply circuit can, in such case, be associated, in each case, with, for example, exactly one field device and can be accommodated together with the evaluating circuit associated with the respective field device—for example, joined to one corresponding fieldbus adapter—in one, shared, electronics housing, e.g. embodied as a hatrail-module. It is, however, also quite usual to accommodate supply circuits and evaluating circuits, in each case, in separate, on occasion, spatially remote from one another, electronics-housings and to wire them appropriately to one another via external lines.

Industrial-strength, electrical or, also, electronic, devices must, as is known, satisfy very high protection requirements, especially as regards the shielding of the therein placed, electrical components against external environmental influences, such as protection against possible contacting of voltage-containing components and/or as regards suppression of electrical, igniting sparks in the in the case of malfunction.

To this belongs (such as, for example, also explained in DE-A 10,041,166), especially, the requirement that an electrical current, which, for example, in the case of short-circuiting, could flow via the housing to ground, or earth, must not exceed a maximum allowable, highest value. In the case of connection of the electrical device to 250 V, this allowable, highest value amounts, for example, to 10 mA. If these requirements are fulfilled, then the device meets, at least, the requirements of Protection Class 11; i.e. an electrical device with protective isolation is involved. For implementing these requirements, it is, accordingly, necessary, that the housing of the electrical device be sufficiently insulated relative to all voltage-carrying parts of the device. Such insulation is especially necessary, when the housing, itself, is made of electrically conductive material, for example, a metal.

Electrical devices, which are also to be operated in explosion-endangered areas, must, moreover, also satisfy very high safety requirements as regards explosion protection. In such case, of concern, especially is safely preventing the formation of sparks, or, at least, assuring that a spark possibly occurring in the interior of a closed space has no effects on the environment, in order, so, safely to avoid the potentially possible triggering of a explosion. As, for example, also explained, in this connection, in the initially mentioned EP-A 1 669 726, U.S. Pat. No. 6,366,436, U.S. Pat. No. 6,556,447 or US-A 2007/0217091, there are distinguished, with reference to explosion protection, various ignition protection types, which are correspondingly manifested, in each case, also in relevant standards and norms, such as e.g. in US-American standard FM3600, international standard IEC 60079-18 or the norms DIN EN 50014 if, concerning electrical operating means for explosion endangered areas.

Thus, e.g., according to the European standard EN 50 020:1994, explosion protection is provided, when devices are constructed according to the therein defined, ignition protection type, or, also, protection class, with the name “Intrinsic Safety” (Ex-i). According to this protection class, the values of the electrical variables, current, voltage and power, in a device have to lie, at all times, in each case, below predetermined limit values. The three limit values are so selected, that, in the case of malfunction, e.g. by short-circuiting, the maximum occurring heat is not sufficient to produce an igniting spark. Electrical current is kept under its predetermined limit value e.g. by resistors, voltage e.g. by Zener diodes, and power by appropriate combining of current- and voltage-limiting components.

In European standard EN 50 019:1994, a further protection class is provided, with the name “Increased Safety” (Ex-e). In the case of devices constructed according to this protection class, ignition- or explosion-protection is achieved by making the spatial separations between two different electrical potentials so large, that a spark formation cannot, due to distance, occur, in the case of malfunction. This can, however, lead, in given circumstances, to the fact that circuit arrangements must have very large dimensions, in order to satisfy these requirements.

Another protection class is additionally provided in the European standard EN 50 018:1994, namely the ignition protection type “Pressure-Resistant Encapsulation” (Ex-d). Electrical devices constructed according to this protection class must have a pressure-resistant housing, for assuring that an explosion occurring in the interior of the housing cannot be transmitted to the exterior. Pressure-resistant housings are, in order that they have sufficient mechanical strength, constructed with comparatively thick-walls.

A further European standard, namely DIN EN 50028, relates to the protection class “Potting-Compound Encapsulation” (Ex-m). Involved, in such case, is a type of ignition protection, wherein the components and/or assemblies of the electrical device, which could potentially ignite an explosion-capable atmosphere by sparks or by heating, are encapsulated by filling the space of the chamber surrounding the components and/or assemblies with, most often, elastomeric and/or foamed, embedding compound, such that a contact is largely excluded for the explosion endangered atmosphere, and, so, an ignition can be prevented.

In the USA, Canada, Japan and other countries, standards exist which are comparable with the aforementioned European norms.

The, for the mentioned reasons, necessary encapsulation of electrical components and/or assemblies of electrical devices of the discussed kind with embedding compound—be it out of reasons of electrical insulation of voltage-containing parts, out of reasons of further explosion protection, or for the purpose of shielding against dust and/or moisture—is most often thereby implemented, that the pertinent assembly-accommodating chamber of the housing, especially in the context of an automated manufacturing process, is filled with a firstly flowable, reactive, multicomponent system and such is allowed to cure to a solid, most often, elastomeric, synthetic material, such as, for instance, epoxide resin or polyurethane. After the curing of such synthetic material within the chamber, there is then present a solid, on occasion, also elastic, three-dimensional, synthetic-material body, which essentially form-fittingly surrounds the components and/or assemblies to be encapsulated. As required, this can include an adhesive contacting. Other synthetic materials, especially also elastomeric, synthetic materials, finding application as embedding compound for electrical components and/or assemblies, include, for example, also silicone and/or rubber. Methods for manufacture and/or introduction of such three-dimensional, synthetic-material bodies (serving as embedding compound) by means of casting methods are described, for example, in the initially mentioned EP-A 1 669 726, U.S. Pat. No. 6,051,783 or also DE-A 198 39 458.

Besides the aforementioned potting method involving casting, there is proposed, for example, in DE-A 100 41 166, a further opportunity for introducing such three-dimensional synthetic material body into the corresponding chamber to serve as embedding compound for electrical components and/or assemblies therein. In this other technique, such synthetic material body is formed outside of the chamber with dimensions to fit the chamber, and, in such case, compounded to be sufficiently elastic, that, in the cured state, it is subsequently insertable into the chamber.

In the application of three-dimensional, synthetic material bodies (manufactured in whatever way) as embedding compound for electrical components and/or assemblies, there is, however, as discussed, for example, also in EP-A 1 669 726, a special problem therein, that, in the case of temperature changes and the accompanying absolute, as well as also relative, volume changes of housing and embedding compound, there is possibly increased pressure on encapsulated components and/or increased mechanical stresses in the housing and/or in the embedding compound. In the case of a completely filled chamber, it is quite possible that one must expect damage of the housing and/or also of the therein accommodated, electrical components.

Moreover, there is, in the case of embedding compounds manufactured by means of reactive, multicomponent systems, such as e.g. polyurethane or epoxide resin, a further problem therein, that in addition to the thermally induced stresses, technologically dependently, also mechanical stresses can arise on the basis of the almost unavoidable volume shrinkage occurring during the curing.

In addition, such volume changes—be they now technologically dependent and/or thermally Induced—can also lead to rather undesired releases of the embedding compound from the wall of the housing, whereby not only the sealing action of the embedding compound is reduced, but also, in uncontrollable manner, new current leakage- and/or ignition-paths can be opened. For reducing such mechanical stresses, for example, in DE-A 198 39 458, it is recommended to apply polyurethane- or epoxide resin-foam as embedding compound. Furthermore, it has been proposed, in addition, in EP-A 1 669 726 to use as embedding compound likewise a porous, especially sponge-like structured, and, thus, highly compressible, synthetic material, such as, for instance, addition cross-linked, silicone rubber.

Although with such foamed, porous, embedding compounds, the aforementioned stress problem can be quite effectively met, investigations with such foams have, however, shown, that, for example, as a result of practically unavoidable fluctuations of the boundary conditions of the manufacturing process, the quality of such foams can also fluctuate to a considerable extent within a charge and, thus, reproducibility of such embedding compounds within a narrow tolerance range is scarcely assured. As a result of this,—if at all—regretfully only with considerable technical effort, especially as regards calibration, adjusting and conducting of the most often, largely automated, manufacturing process, can reliable statements be made concerning the actual properties of the respective embedding compound and, as a result, the required high quality and functional safety required for the embedding compounds of electrical devices of the type being discussed, in special measure, however, also for field devices as a whole, cannot, without more, be assured.

### SUMMARY OF THE INVENTION

An object of the invention is, therefore, to improve electrical devices of the type being discussed, such that the aforementioned disadvantages can be prevented. In addition, it is an object of the invention that such electrical devices can, on the one hand, be provided with embedding compound of, in each case, sufficiently reproducible properties using a manufacturing process which is as simple as possible to calibrate, and that such electrical devices can, on the other hand, be operated faultlessly over an, as broad as possible, allowable temperature range and, in such case, also possibly placed safety-requirements, especially as regards explosion protection and/or contact protection, are reliably fulfilled.

To achieve these objects, the invention resides in an electrical device, for example one embodied as a measuring- and/or switching-device of industrial measuring- and automation-technology, and/or an electronic device, having at least one housing, which has at least one chamber, for example a pressure-tightly and/or explosion-resistantly sealed chamber, for accommodating, for example, electrical, electronic and/or electromechanical components and/or assemblies of the device. According to the invention, it is additionally provided that a space of such chamber surrounding the components and/or assemblies is at least partially, for example also completely, and/or in an ignition protection type “Ex-m”-guaranteeing manner, filled with embedding compound, in which is incorporated, for example, essentially spherically shaped and/or gas-filled, hollow bodies, such as, for instance, microballoons.

Additionally, the invention resides also in the use of a such device for measurement of a physical and/or chemical, measured variable of a medium conveyed in a pipeline, especially a pipeline extending, at least sectionally, through an explosion-endangered zone, and/or a medium held in a container, especially a container within an explosion-endangered danger zone.

In a first embodiment of the invention, it is provided, that the embedding compound is formed by means of filling of the chamber, earlier populated with components or assemblies, especially also the chamber earlier filled with at least a part of the hollow bodies, with a flowable, especially reactive and/or mixed at least with a part of the hollow bodies, multicomponent system. According to a further development of this embodiment of the invention, it is additionally provided, that the embedding compound is formed by means of allowing at least a part of the multicomponent system filled into the chamber to solidify, especially by curing and/or resinification, within the chamber.

Basically, a large number of materials are applicable for implementing the embedding compound. In a second embodiment of the invention, it is, however, provided, that the embedding compound is composed predominantly of an, especially polymeric and/or elastic and/or essentially solid, synthetic material, especially polyurethane. According to a further development of this embodiment of the invention, it is additionally provided, that the synthetic material, especially the essentially solid, synthetic material, is at least predominantly pore-free and/or that the hollow bodies have, at least partially, and/or at least on average, a higher effective compressibility than the synthetic material. Alternatively to or in supplementation of this further development, it is additionally provided that an embedding compound is used, in the case of which a volume ratio of hollow bodies to synthetic material amounts, especially initially, to at least 1:100, especially at least 1:10.

Also applicable as synthetic material is a large number of materials, especially materials which are castable and appliable and/or curable at comparatively low working temperatures, materials such as, for instance, epoxide resin, silicone, etc. In a third embodiment of the invention, it is, however, provided, that polyurethane is used as synthetic material, polyurethane being, especially in comparison to silicone, most often, more cost-favorable, having lower coefficients of thermal expansion and tending, most often, also to outgas less.

Although diameter or size of the used hollow bodies can, basically, be quite different, according to a fourth embodiment of the invention, it is additionally provided, that the hollow bodies have, exclusively or at least predominantly, a largest diameter in the micrometer range.

In a fifth embodiment of the invention, it is provided that hollow bodies are applied having, exclusively or at least predominantly, a largest diameter smaller than 1 mm, especially smaller than 0.5 mm. Developing this embodiment of the invention further, it is additionally provided, that the applied hollow bodies have such a particle size, that the largest diameter lies, at least on average and/or predominantly, between 60 μm and 120 μm.

In a sixth embodiment of the invention, it is provided, that the hollow bodies have a hydrostatic pressure resistance, which is, at least on average and/or predominantly, greater than 300 psi.

In a seventh embodiment of the invention, it is provided, that the hollow bodies have a density, which lies, at least on average and/or predominantly, between 0.08 g/cm³ and 0.12 g/cm³.

In an eighth embodiment of the invention, it is provided, that wherein a volume fraction of the hollow bodies in the embedding compound amounts to at least 1%, especially more than 5%.

In a ninth embodiment of the invention, it is provided, that the hollow bodies are formed by means of an electrically essentially non-conductive material and/or by means of a synthetic material.

In a tenth embodiment of the invention, it is provided, that at least a part of the hollow bodies are embodied as glass-spheres and/or phenolic resin-spheres.

Although, basically, the chamber equipped with the embedding-compound need not be sealed, an eleventh embodiment of the invention additionally provides, that the chamber accommodating at least one component and/or assembly of the device is sealed pressure-tightly and/or explosion-resistantly. In such a case, the advantages of the embedding compound of the invention with an overall higher effective compressibility achieve special importance, since also in such case, unallowably high pressures or stresses in the embedding compound and/or surrounding housing can be very effectively prevented. This is especially also true when the space surrounding the components and/or assemblies is filled with embedding compound also, for example, for implementing the ignition protection type “Ex-m”. The implementing of the device in the aforementioned ignition protection type would be, for example, also quite conducive to the use of the device of the invention in an explosion-endangered area.

In a twelfth embodiment of the invention, the device further includes, electrically connected with components located in the chamber by means of a connecting line, a measuring transducer, which, at least at times during operation, provides, via a connecting line, a measurement signal corresponding with a physical and/or chemical, measured variable of a medium, especially a medium conveyed in a pipeline and/or held in a container.

Starting from inherent disadvantages of the above-explained, conventional devices of the kind being discussed, thus, a basic idea of the invention is, among others, to make the embedding compound used for electrical devices of the kind being discussed, especially those serving as measuring field-devices, on the one hand, as a whole, at least as regards expected thermally related expansions, sufficiently compressible by the introduction of inclusions, while, on the other hand, however, also being able to define, with sufficient safety, and, thus, also, without considerable extra effort, firstly, those inclusions assuring the, as a whole, high compressibility within the embedding compound and, secondly, thus, the embedding compound as a whole as regards quality and operating properties. The required high compressibility as well as also the assured quality of the embedding compound is brought about, according to the invention, by incorporating in the embedding compound hollow bodies, which are, themselves, in comparison at least with the surrounding housing wall, naturally far more yielding and which, for example, in comparison with current elastomeric, synthetic materials, such as polyurethane, epoxide resin, silicone, etc., can have effectively a far higher compressibility. In other words, by the application of the hollow bodies, it is possible in very simple and effective manner, especially also in a defined and reproducible manner, to create, for electrical devices of the kind being discussed, suitable embedding compound, which has, on the one hand, an open-pore structure quite comparable with foams and providing the required compressibility, while, on the other hand, however, not having the uncertainties most often otherwise associated with foam formation as regards quality and operating behavior.

With the invention, thus, an embedding compound for electrical devices is provided for enabling their use also within a broad operating temperature range, since, due to the, as a whole, high compressibility, neither a separating of the embedding compound from the wall surrounding the chamber nor an unallowably high pressure within such is to be feared. This is especially true, because at least the hollow bodies incorporated in the embedding compound can directly absorb mechanical stresses possibly associated with thermally related volume changes of the housing relative to the embedding compound.

### BRIEF DESCRIPTION OF THE DRAWINGS

In particular, there are, now, a large number of opportunities to embody and to develop further the devices of the invention as well as uses of the invention for such devices. In this regard, reference is made to the examples in the figures of the drawing; equal parts are provided in the figures with equal reference characters. In case helpful for overviewability, already mentioned reference characters are omitted in subsequent figures. The figures of the drawing show as follows:

FIG. 1 a perspective view of an electrical device embodied as a measuring device, especially an electrical device embodied as an electromechanical, limit-level sensor, wherein the electrical device includes a housing embodied as an electronics-housing;

FIG. 2 a view of the device of FIG. 1 with sectioned electronics housing, before insertion of a plug serving for sealing a chamber accommodating components and/or assemblies of the device and filled with embedding compound;

FIG. 3 the device of FIG. 2 after insertion of the plug; and

FIG. 4 a partially sectioned view of the device in the assembled state, however, in a somewhat modified form of embodiment relative to the electronics-housing of FIG. 3.

### DETAILED DISCUSSION OF THE DRAWINGS

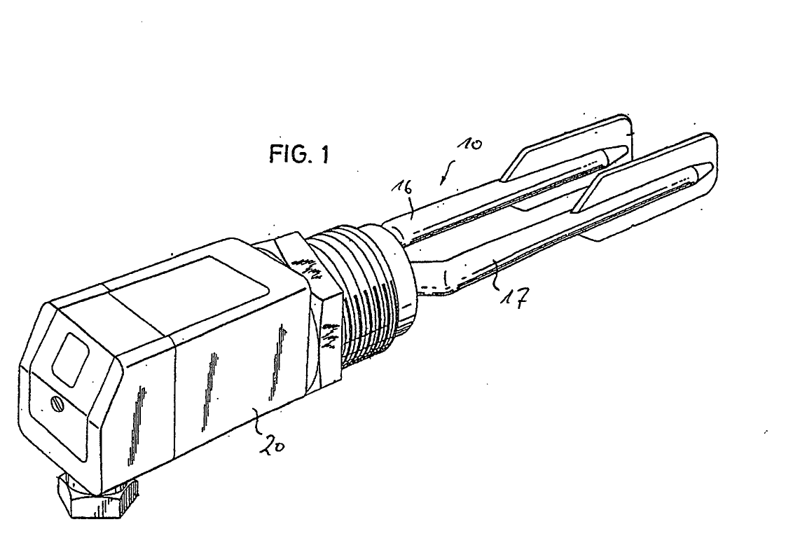

Shown in FIG. 1 is an electrical device, especially an electronic device and/or a device embodied as a measuring- and/or switching-device of industrial measurements- and automation-technology. The device has at least one housing with at least one chamber. The chamber serves, in turn, for accommodating, especially, electrical, electronic and/or electro-mechanical components and/or assemblies of the device.

The device is, additionally, especially, provided for use in the measurement of a physical and/or chemical, measured variable of a medium conveyed in a pipeline extending, for example, at least sectionally, through an explosion-endangered zone, and/or held in a container placed, for example, within an explosion-endangered danger zone. Accordingly, the electrical device can be for example, a Coriolis mass flow measuring device, a density-measuring device, a magneto-inductive, flow measuring device, a vortex, flow measuring device, a ultrasonic, flow measuring device, a thermal, mass-flow measuring device, a pressure measuring device, a fill-level measuring device, a temperature measuring device, a pH-value measuring device, or the like. For this, the device, in a further development of the invention, includes, electrically connected with components located in the chamber by means of a connecting line, especially by means of an at least sectionally flexible connecting line, at least one measuring transducer 10, which, at least at times during operation, provides via the connecting line a measurement signal corresponding with a physical and/or chemical, measured variable of the particular medium to be measured, especially a medium conveyed in a pipeline and/or held in a container.

For the further explanation of the invention, selected for the example of an embodiment shown in the figures is an electromechanical, fill-level sensor—only as illustrative and without limitation thereto. Such electromechanical, fill-level sensor is well established in industrial measurements-technology and serves for monitoring a predetermined fill level in a container. Sensors of this type are known to those skilled in the art e.g. also from the initially mentioned U.S. Pat. No. 6,051,783 and U.S. Pat. No. 6,539,819.

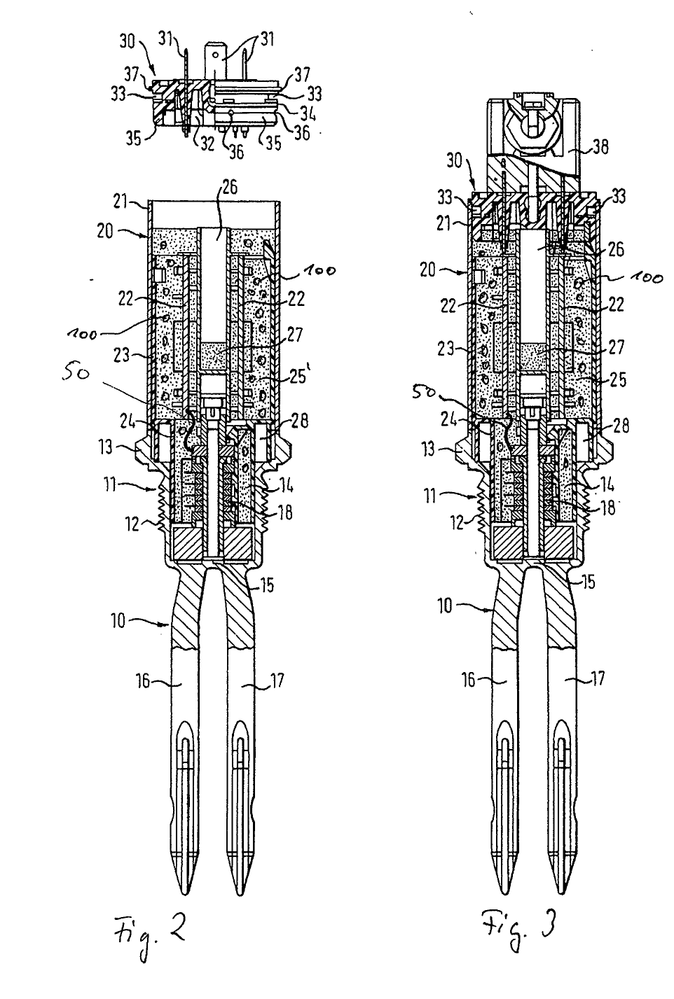

The device constructed as a fill level sensor in the example of an embodiment includes, as evident from the combination of FIGS. 1 and 2 and/or 3, a measuring transducer housing 11 developed as a screw-in element with a threaded section 12 and a hexagonal head 13.

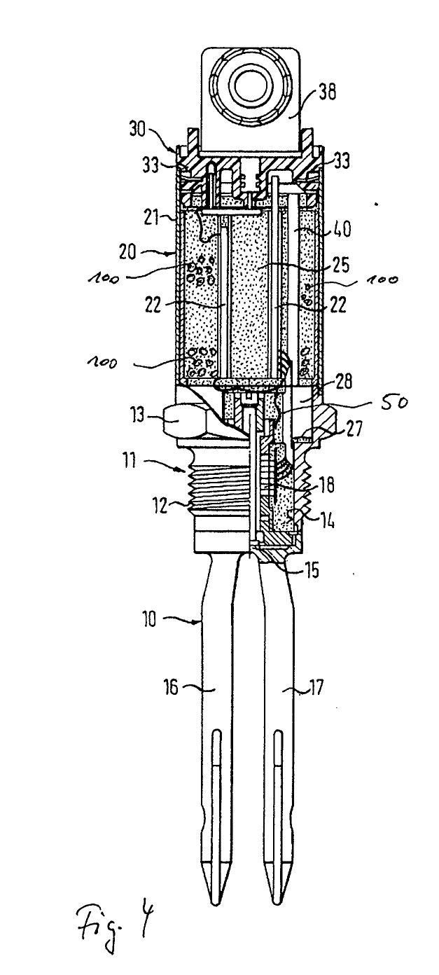

A hollow inner space of the screw-in element for forming the chamber 14 of the housing is, as illustrated schematically in FIGS. 2 and 3, sealed on the lower end by a membrane, or diaphragm, 15, on which, in turn, the membrane-side ends of two oscillatory rods 16 and 17 are secured. By means of the screw-in element, the device, serving here as a limit-level monitoring, fill level sensor, is so secured, sealed against leakage of medium, in an internally threaded opening of a container wall (not shown), that the oscillatory rods 16, 17 extend into the interior of the containment and come in contact with the fill substance, when it reaches the limiting fill level to be monitored.

In the hollow inner space 14 of the measuring transducer housing 11, an electromechanical transducer arrangement 18 is located, formed by a stack of piezoelectric elements. The transducer arrangement 18 contains exciting transducers and receiving transducers. When an electrical alternating voltage is applied to the exciting transducers, they cause the membrane, or diaphragm, 15 to execute oscillations, which are transmitted to the oscillatory rods 16 and 17, so that these rods execute opposed oscillations transversely to their longitudinal direction. When mechanical oscillations act on the receiving transducers, they produce an electrical alternating voltage with the frequency of the mechanical oscillations.

An associated electronics electrically communicating with the measuring transducers via transducer arrangement 18 contains an amplifier, which receives on its input the alternating voltage produced by the receiving transducers and transmits on its output the amplified alternating voltage to the exciting transducers. Thus, the mechanical oscillatory system formed by the membrane, or diaphragm, 15 and the oscillatory rods 16, 17, lies via the transducer arrangement 18 in the feedback loop of the amplifier, so that it excites oscillations with an eigenresonance frequency. The functioning of such a fill-level sensor rests, as is known, on the fact that an eigenresonance frequency of the mechanical oscillatory system for the case, in which the oscillatory rods 16, 17 are not in contact with to the fill substance to be monitored, is higher to a degree sufficient for the detection, than for the case, in which the oscillatory rods 16, 17 penetrate into the fill substance. The associated electronics contains, therefore, additionally, an evaluating circuit, which determines, whether the frequency of the alternating voltage output by the amplifier, which agrees with the frequency of the mechanical oscillation, lies above or below a predetermined threshold value. When this frequency lies above the threshold value, this means, that the oscillatory rods 16, 17 are oscillating in air, thus the fill substance has not reached the fill level to be monitored. When, in contrast, the frequency lies under the threshold value, this means, that the fill substance has reached or exceeded the fill level to be monitored in the container.

For accommodating the electronics, which can be connected with the transducer arrangement 18 and, thus, with the measuring transducer 10, such as connection by means of sectionally flexible and/or sectionally rigid, connecting line(s) 50, a housing 20, here, thus, an electronics housing, is placed on the end of the screw-in element situated outside of the container. The wall of the electronics-housing 20 is formed by a metal tube 21, which, as evident from FIGS. 2 and 3, is secured at one end via a sealed connection to the screw-in element serving as measuring transducer housing 11 and which is open at its opposite end. The electronics is formed in usual manner by electrical and/or electronic components, which are mounted on circuit boards 22 to form corresponding electronic and/or electrical assemblies. Placed in the interior of the electronics housing 20 is a sleeve 23 in the form of a plastic, molded part. Sleeve 23 lies against the inner surface of the metal tube 21 and surrounds the electronics in the interior of the electronics housing 20. The sleeve 23 has on its lower end an extension 24 of smaller diameter, which protrudes into the hollow inner space 14 of the screw-in element 11 and surrounds the transducer arrangement 18. Sleeve 23 facilitates the mounting of the electronics in the electronics housing 20, since the electronics can thereby be arranged in the sleeve 23 outside of the electronics housing 20 and then inserted together with the sleeve 23 into the electronics housing 20.

For protection of the utilized components and/or for assuring safety requirements possibly placed on the device, as also schematically illustrated in FIGS. 2 and 3, additionally a space 14′ of the mentioned chamber surrounding the components and/or assemblies (here, thus, a part of the inner space 14 remaining after insertion of the components or assemblies) is at least partially filled with embedding compound. If conditions require, space 14′ may also be filled completely and/or in a manner guaranteeing ignition protection type “Ex-m”. Especially, it is provided, that the embedding compound is composed, at least partially, of a synthetic material 25, such as, for instance, polyurethane, silicone, epoxide resin or the like.

For additional reduction of the potential for danger stemming from the device, especially also for lowering risk of an igniting of an atmosphere surrounding the device during operation, it can be of advantage to embody the chamber additionally such that it is sealed pressure-tightly and/or explosion-resistantly. Alternatively thereto or in supplementation thereof, the embedding compound of an additional embodiment of the invention, especially for the purpose of assuring the aforementioned ignition protection type “Ex-m”, is predominantly composed of polymeric and/or elastic, synthetic material, especially a polyurethane.

In order to make the embedding compound formed by means of solid, synthetic material sufficiently compressible, especially with reference to thermal and/or mechanical loads possibly occurring during operation, the device of the invention further includes, incorporated into the embedding compound, hollow bodies 100, which are compressible, especially in comparison with solid polyurethane and/or silicone. The hollow bodies 100 can, for example, be filled with an, especially inert, gas and/or can be of essentially spherical form—thus, provided as so-called microballoons or microspheres. Furthermore, the hollow bodies 100 themselves, or, rather, their shells, can be formed by means of an electrically non-conductive material and/or a synthetic material. Especially applicable, in such case, are glass-spheres and/or phenolic resin-spheres as excellently suitable hollow bodies for implementing the invention, such as are available e.g. under the designation Ucar® BJO-0930. These have, for example, a hydrostatic pressure resistance of more than 300 psi, as well as a density, for instance, between 0.08 g/cm³ and 0.12 g/cm³.

According to an embodiment of the invention, for the mentioned case, in which the embedding compound is also formed by means of a synthetic material 25, thus serving also as matrix for the hollow bodies 100, it is additionally provided, that the hollow bodies, at least on average and/or as a whole, have a higher effective compressibility than the synthetic material, which may be, depending on the circumstances, itself largely incompressible. To this end, it is additionally provided, at least partially, especially predominantly, that hollow bodies are used, which have, in comparison with the applied synthetic material, a higher, volume-referenced, specific compressibility.

According to an additional embodiment, it is, therefore, further provided, that hollow bodies and synthetic material are used in such amounts, that a volume ratio of hollow bodies 100 to synthetic material within the embedding compound 25 amounts, in the end, to at least 1:100, especially at least 1:10, and/or that a volume fraction of hollow bodies to total embedding compound amounts to at least 1%, especially more than 5%. Alternatively thereto or in supplementation thereof, it is additionally provided, that hollow bodies are used having a particle size, at least on average and/or predominantly, smaller than 1 mm, especially smaller than 0.5 mm. Especially, however, it is provided, that the hollow bodies have, at least on average, and/or predominantly, a particle size lying between 60 μm and 120 μm.

In a further embodiment of the invention, the hollow bodies are distributed, such as indicated in FIGS. 2 and 3, as uniformly as possible in the embedding compound, whereby the embedding compound, in spite of incorporated “disturbances” in the form of the hollow bodies, can be embodied quasi isotropically. Alternatively thereto, the hollow bodies can, however, also, be arranged with spatial concentrations, such as indicated in FIG. 4, for example, layer-wise and/or heaped, in the embedding compound, for example in order to be able, with targeting, to match its compressibility and/or its expansion behavior to actual conditions within chamber or the housing.

For assuring good reproducibility of the embedding compound also in the course of automated manufacture, coupled with, as much as possible, constant high quality, it can additionally be of advantage to make the synthetic material—apart from the incorporated hollow bodies—otherwise essentially solid and/or at least predominantly pore-free.

Other hollow bodies or synthetic material-hollow body-mixtures suitable for the implementing the embedding compound suitable are described, moreover, for example, also in U.S. Pat. No. 6,207,730.

The embedding compound itself can be manufactured in simple manner e.g. by charging the chamber, earlier appropriately populated with components or assemblies—optionally also earlier provided with at least a part of the required hollow bodies—with a flowable, especially reactive and/or at least mixed with a part of the hollow bodies, multicomponent system. For the case, in which the embedding compound is to be embodied, in the end, as a solid, three-dimensional body, the embedding compound is finally formed by allowing at least a part of multicomponent system charged into the chamber to solidify therein, for example, by curing and/or resinification of the multicomponent system as a result of chemical reactions permitted therein, reactions such as, for instance, polyaddition, addition crosslinking, polymerization or the like. Alternatively thereto or in supplementation thereof, it is also possible, however, such as proposed, for example, also in the initially mentioned DE 100 41 166, to allow at least a part of the synthetic material and, as a result, of the embedding compound as a whole, to remain lastingly flowable.

A suitable method for the manufacture of the embedding compound is disclosed, for example, in the initially mentioned U.S. Pat. No. 6,051,783. In reference thereto, after the sleeve 23 with the electronics has been inserted into the electronics housing 20, the hollow spaces in the electronics housing 20 and in the screw-in element 11 are filled with the multicomponent system serving as potting compound 25′. This is charged in liquid state through the open end of the electronics housing 20 and then appropriately cured. The potting compound can be, for example, a flowable, prepolymer system mixed with alcohol and a suitable catalyst or a rather gel-like, two component, silicone rubber.

For charging the potting compound, the device is placed in the vertical position illustrated in FIG. 1, in which the open end of the electronics housing 20 lies above. In use, in contrast, the device can be mounted in any position; ordinarily, fill-level sensors of the described kind are mounted horizontally in the sidewall of the containment at the level of the fill level to be monitored.

The terms “above” and “below” used in the following refer to the illustrated charging position of the drawing.

FIG. 1 shows the device after charging of the potting compound 25′ shown by the speckling. For automating the manufacture, an, as much as possible, equally metered amount is measured and charged.

The illustrated electronics housing 20 is so embodied, that, independently of possible manufacturing- and metering-fluctuations and independently of different component sizes at constant metered charge amount, the desired fill level is exactly maintained. For this purpose, an overflow tube 26 is so placed in the electronics housing 20, that its upper end lies at the desired fill level below the upper edge of the electronics housing. In the case of the example of an embodiment shown in FIGS. 1 and 2, the overflow tube 26 is arranged coaxially with electronics housing 20. It is sealed on the lower end and has a relatively large diameter, so that its volume is essentially greater than the largest arising, overflow amount of the potting compound 25′. The charged amount of the potting compound 25′ is so measured, that, even in the case of the largest arising, residual volume, the desired charge level reached is. In the case of smaller residual volume, the excess potting compound flows into the overflow tube 26. This overflow amount 27 collects in the lower part of the overflow tube 26 serving as collection space. As a result of the relatively large volume of the overflow tube, there remains, however, present in the overflow tube 26, a significant air volume, even in the case of the largest arising, overflow amount 27.

Thus, the charge level of the potting compound 25′ in the electronics housing 20 is always maintained exactly at the level of the upper edge of the overflow tube 26.

In the transition region between the electronics housing 20 and the screw-in element 11, there is formed on the sleeve 23 a ring-shaped air chamber 28, which has no connection with the volume receiving the potting compound 25′, so that the air chamber 28 also remains filled with air after the charging of the potting compound 25′.

Immediately after the charging of the potting compound 25′, while such is still in the liquid state, the open end of the electronics housing 20 is sealed by a plug 30, which is shown in FIG. 2 above the still open, electronics housing 20. Plug 30 is, for example, a molded part of synthetic material, manufactured by injection molding, and serves, besides for sealing the electronics housing 20, also for connection of the electronics accommodated in the electronics housing 20 with external lines. For this purpose, metal contact parts 31 are supplied in the plug 30.

Contact parts 31 have, on the underside of the plug 30 facing the interior of the electronics housing 20, projecting contact tips, and, formed on the externally lying, upper side of the plug 30, flat contact blades, onto which a plug socket can be applied. Into the underside of the plug 30, a cavity 32 is formed, and a peripheral groove 33 runs annularly around the plug 30. The edge region 34 of the plug 30 lying below the peripheral groove 33 transitions into a peripheral edge 35, which surrounds the cavity 32 and has a somewhat smaller outer diameter than the edge region 34. Through this peripheral edge 35 extend air removal holes 36 from the cavity 32 to the outer periphery. A projecting edge 37 formed above the peripheral groove 33 limits penetration of the plug 30 into the electronics housing 20. When plug 30 is completely inserted, edge 37 lies on the upper edge of the electronics housing 20 (FIG. 3).

Upon insertion of the plug 30 into the open end of the electronics housing 20, air above the surface of the potting compound 25′ can escape to the exterior through the air removal holes 36. Upon further insertion of the plug 30, the tips of the contact parts 31 and the peripheral edge 35 submerge into the potting compound 25′, whereby still some potting compound is displaced, which flows off into the overflow tube 26. When finally plug 30 is completely inserted (FIG. 3), overflow tube 26 protrudes into the cavity 32, so that also a part of the cavity 32 is filled with potting compound 25′.

Between the edge region 34 of the plug 30 and the inner surface of the metal tube 21, there is a gap, which is so dimensioned, that potting compound, which penetrates into the intermediate space between the peripheral edge 35 and the metal tube 21, is drawn by capillary action upwards into the peripheral groove 36. This rising potting compound collects in the peripheral groove 33, whereby two effects are achieved: On the one hand, it is prevented, that the rising potting compound escapes externally, and, on the other hand, the potting compound gathered in the peripheral groove 33, when cured, provides a good sealing of the gap between the plug 30 and the wall of the electronics housing 20.

FIG. 3 shows the device in the completely assembled state. The tips of the contact parts 31 protruding from the underside of the plug 30 are in contact with the countercontact pieces of the electronics. Plugged onto the upwardly extending, flat contact blades of the contact parts 31 is a cable-connected socket 38. In this way, connection of the cable to the electronics in the electronics housing 20 is produced.

Comparatively soft potting compounds, such as, for instance, silicone rubber, have the properties that they conduct heat well and that they expand relatively strongly in the case of heating. The air volume enclosed in the air chamber 44 acts, during operation of the device, as a temperature barrier between the screw-in element 11 connected with the container and the electronics housing 20, whereby heat transport from the fill level sensor to the electronics reduced is. The air volume present in the overflow tube 26 supplements the incorporated hollow bodies in absorbing part of the excess pressure arising in the electronics housing 20, when the synthetic material of the embedding compound 25 expands in the case of heating.

FIG. 4 shows a modified form of embodiment of the electronics housing 20, which is added on to a fill level sensor of the same kind as in FIGS. 1 and 2. The components of the measuring transducer 10 here (embodied as a fill level sensor) and the electronics housing 20 are largely the same as those of the form of embodiment of FIGS. 2 and 3 and are, therefore, referenced with equal reference characters to those used for FIGS. 2 and 3. A difference between the form of embodiment of FIG. 4 and that of FIGS. 2 and 3 is, among others, the overflow tube, which, in FIG. 4, bears the reference character 40. The overflow tube 40 of FIG. 4 is no longer coaxial with the electronics housing 20, but, instead, occupies a position displaced from the axis, and it is connected on its lower end with the air chamber 28 formed in the screw-in element 11. Therefore, in this case, the air chamber 28 serves also as a collection space for the overflow amount 27 of the potting compound 25′, which collects on the floor of the air chamber 28. Additionally, an excess pressure occurring in the electronics housing 20 is absorbed by the total air volume in the air chamber 28 and in the overflow tube 40. For both reasons the overflow tube can have an essentially smaller cross section than in the case of the form of embodiment of FIGS. 2 and 3.

1. An electrical device, especially one embodied as a measuring- and/or switching-device of industrial measurements and automation technology and/or an electronic device, comprising:
at least one housing, which has at least one chamber, especially a chamber accommodating electrical, electronic and/or electromechanical components and/or assemblies of the device, said chamber being pressure-tightly and/or explosion-resistantly sealed, wherein:
a space of said chamber surrounding the components and/or assemblies is at least partially, especially completely and/or in an ignition protection type “Ex-m” guaranteeing manner, filled with embedding compound, in which are incorporated hollow bodies, especially essentially spherically shaped hollow bodies and/or hollow bodies filled with gas, especially hollow bodies in the form of microballoons.

2. The electrical device as claimed in claim 1, wherein:
the embedding compound is formed by means of charging the chamber, earlier populated with components or assemblies, especially also earlier filled with at least a part of the hollow bodies, with a flowable, multi-component system, especially a multi-component system which is reactive and/or at least mixed with a part of the hollow bodies.

3. The electrical device as claimed in claim 1, wherein:
the embedding compound is formed by means of allowing at least a part of the multicomponent system charged into said chamber to solidify, especially by curing and/or resinification.

4. The electrical device as claimed in claim 1, wherein:
the embedding compound comprises, predominantly, a synthetic material, especially a polymeric and/or elastic and/or essentially solid, synthetic material, especially polyurethane.

5. The electrical device as claimed in claim 4, wherein:
the, especially essentially solid, synthetic material is, at least predominantly, pore-free.

6. The electrical device as claimed in claim 4, wherein:
the hollow bodies have, at least partially and/or at least on average, a higher effective compressibility than the synthetic material.

7. The device as claimed in claim 4, wherein:
a volume ratio of said hollow bodies to synthetic material amounts, especially initially and/or nominally, amounts to at least 1:100, especially at least 1:10.

8. The device as claimed in claim 1, wherein:
said hollow bodies have a particle size, which, at least on average and/or predominantly, is smaller than 1 mm, especially smaller than 0.5 mm.

9. The device as claimed in claim 1, wherein:
said hollow bodies have a particle size, which, at least on average and/or predominantly, lies between 60 μm and 120 μm.

10. The device as claimed in claim 1, wherein:
said hollow bodies have a hydrostatic pressure resistance, which is, at least on average and/or predominantly, greater than 300 psi.

11. The device as claimed in claim 1, wherein:
said hollow bodies have a density, which, at least on average and/or predominantly, lies between 0.08 g/cm³ and 0.12 g/cm³.

12. The device as claimed in claim 1, wherein:
a volume fraction of said hollow bodies relative to the embedding compound amounts to at least 1%, especially more than 5%.

13. The device as claimed in claim 1, wherein:
said hollow bodies are formed by means of an electrically non-conductive material and/or a synthetic material.

14. The device as claimed in claim 1, wherein:
at least a part of said hollow bodies is embodied as glass-spheres and/or phenolic resin-spheres.

15. The device as claimed in claim 1, further comprising:
a measuring transducer electrically connected with components located in said chamber by means of a connecting line and providing, at least at times during operation, via said connecting line, a measurement signal corresponding to a physical and/or chemical, measured variable of a medium, especially a medium conveyed in a pipeline and/or held in a container.

16. Use of a device as claimed in claim 1, for measuring a physical and/or chemical, measured variable of a medium conveyed in a pipeline, especially a pipeline extending at least sectionally through an explosion-endangered, danger zone, and/or held in a container, especially a container placed within an explosion-endangered, danger zone.
